(19) United States
(12) Patent Application Publication
(10) Pub. No.: US 2026/0293737 A1
(43) Pub. Date: Sep. 24, 2026

(54) SEMICONDUCTOR ELEMENT AND SEMICONDUCTOR DEVICE

(71) Applicant: ROHM CO., LTD., Kyoto-shi (JP)

(72) Inventors: Hirofumi TANAKA, Kyoto-shi (JP); Masaya UKITA, Kyoto-shi (JP)

(21) Appl. No.: 19/685,965

(22) Filed: May 22, 2026

Related U.S. Application Data
(63) Continuation of application No. PCT/JP2024/040484, filed on Nov. 14, 2024.

(30) Foreign Application Priority Data
Nov. 30, 2023 (JP) 2023-202582

(51) Int. Cl. H10W 72/20; H10W 72/00; H10W 72/29; H10W 72/90

(52) U.S. Cl. CPC H10W 72/244; H10W 72/012; H10W 72/019; H10W 72/29; H10W 72/9223; H10W 72/923

(57) ABSTRACT

A semiconductor element includes a main body, an electrode, a redistribution wiring, a first protective film, and a first intermediate layer. The electrode is located on one side of the main body in a first direction. The redistribution wiring is located opposite the main body with respect to the electrode. The first protective film is located on the same side as the redistribution wiring with respect to the electrode. The first protective film overlaps with the redistribution wiring as viewed in the first direction. The first intermediate layer includes a first portion located between the redistribution wiring and the first protective film. The first portion is in contact with the first protective film. The first intermediate layer is an insulator and contains an inorganic compound. The adhesion strength of the first protective film to the first intermediate layer is higher than the adhesion strength of the first protective film to the redistribution wiring.

### TECHNICAL FIELD

The present disclosure relates to a semiconductor element and a semiconductor device incorporating the semiconductor element.

### BACKGROUND ART

JP-A-2014-165335 discloses an example of a semiconductor element (a semiconductor device in JP-A-2014-165335). The semiconductor element has a substrate having an element formation surface, a pad terminal provided on the element formation surface, a Cu redistribution wiring extending out from the pad terminal, an organic film covering the Cu redistribution wiring, and a resin film covering the organic film. The surface of the Cu redistribution wiring includes a roughened surface. The organic film is in contact with the roughened surface. With such a configuration, the organic film exerts an anchoring effect on the Cu redistribution wiring. Furthermore, because the affinity between the organic film and the resin film is relatively high, the adhesion strength of the resin film to the organic film is enhanced. This suppresses delamination of the resin film from the Cu redistribution wiring layer.

The manufacture of the semiconductor device disclosed in JP-A-2014-165335 requires the surface roughening process on the surface of the Cu redistribution layer and formation of an organic film covering the surface. The roughening process is performed by immersing the surface of the Cu redistribution wiring, which is formed by electroplating, in an etching solution. During the roughening process, attention must be paid to manufacturing control, such as the immersion time in the etching solution, to prevent disconnection of the Cu redistribution wiring. Thus, the manufacture of this semiconductor element presents the challenge of requiring a larger amount of labor.

### BRIEF DESCRIPTION OF THE DRAWINGS

FIG. 1 is a sectional view of a semiconductor element according to a first embodiment of the present disclosure.

FIG. 2 is a partial enlarged view of FIG. 1, showing the area near an electrode.

FIG. 3 is a partial enlarged view of FIG. 1, showing the area near a terminal.

FIG. 4 is a sectional view illustrating the first step of a manufacturing process for the semiconductor element shown in FIG. 1.

FIG. 5 is a sectional view illustrating the second step of the manufacturing process for the semiconductor element shown in FIG. 1.

FIG. 6 is a sectional view illustrating the third step of the manufacturing process for the semiconductor element shown in FIG. 1.

FIG. 7 is a sectional view illustrating the fourth step of the manufacturing process for the semiconductor element shown in FIG. 1.

FIG. 8 is a sectional view illustrating the fifth step of the manufacturing process for the semiconductor element shown in FIG. 1.

FIG. 9 is a sectional view illustrating the sixth step of the manufacturing process for the semiconductor element shown in FIG. 1.

FIG. 10 is a sectional view illustrating the seventh step of the manufacturing process for the semiconductor element shown in FIG. 1.

FIG. 11 is a sectional view illustrating the eighth step of the manufacturing process for the semiconductor element shown in FIG. 1.

FIG. 12 is a sectional view illustrating the ninth step of the manufacturing process for the semiconductor element shown in FIG. 1.

FIG. 13 is a sectional view illustrating the tenth step of the manufacturing process for the semiconductor element shown in FIG. 1.

FIG. 14 is a sectional view illustrating the eleventh step of the manufacturing process for the semiconductor element shown in FIG. 1.

FIG. 15 is a sectional view illustrating the twelfth step of the manufacturing process for the semiconductor element shown in FIG. 1.

FIG. 16 is a sectional view showing a semiconductor device incorporating the semiconductor element shown in FIG. 1.

FIG. 17 is a sectional view of a semiconductor element according to a second embodiment of the present disclosure.

FIG. 18 is a partial enlarged view of FIG. 17, showing the area near an electrode.

FIG. 19 is a partial enlarged view of FIG. 17, showing the area near a terminal.

FIG. 20 is a sectional view illustrating the fifth step of a manufacturing process for the semiconductor element shown in FIG. 17.

FIG. 21 is a sectional view illustrating the sixth step of the manufacturing process for the semiconductor element shown in FIG. 17.

FIG. 22 is a sectional view of a semiconductor element according to a third embodiment of the present disclosure.

FIG. 23 is a partial enlarged view of FIG. 22.

FIG. 24 is a sectional view illustrating a step subsequent to the eighth step of the manufacturing process for the semiconductor element shown in FIG. 22.

FIG. 25 is a sectional view illustrating a step subsequent to the step shown in FIG. 24 of the manufacturing process for the semiconductor element shown in FIG. 22.

FIG. 26 is a sectional view of a semiconductor element according to a fourth embodiment of the present disclosure.

FIG. 27 is a partial enlarged view of FIG. 26.

### DETAILED DESCRIPTION OF EMBODIMENTS

The present disclosure is described below in detail with reference to the accompanying drawings.

### First Embodiment

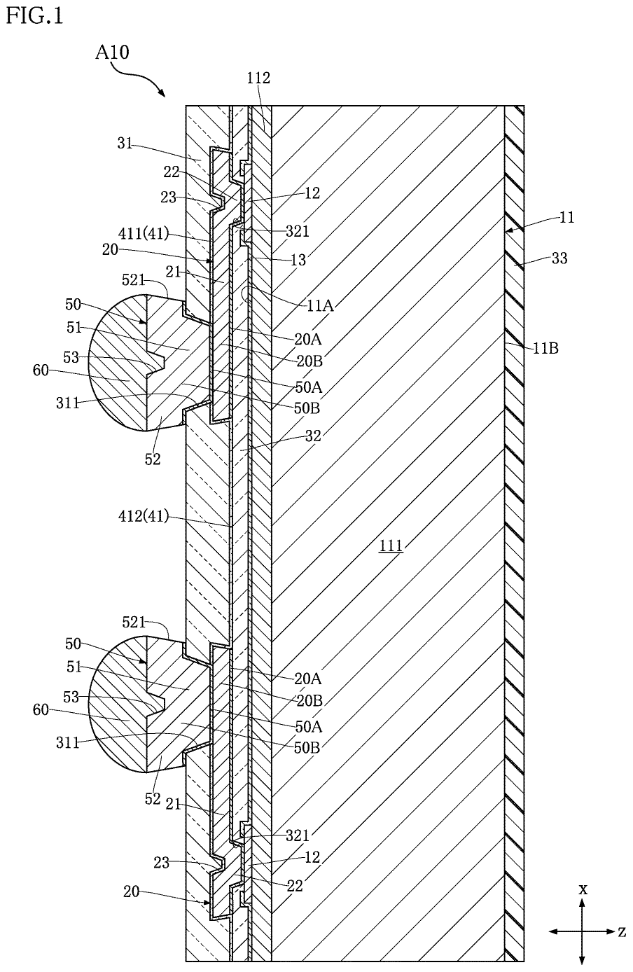

A semiconductor element A10 according to a first embodiment of the present disclosure will be described based on FIGS. 1 to 3. The semiconductor element A10 is, for example, an LSI (Large Scale Integration) referred to as a Wafer Level-Chip Scale Package (WL-CSP). The semiconductor element A10 includes a main body 11, a plurality of electrodes 12, a passivation film 13, a plurality of redistribution wirings 20, a first protective film 31, a second protective film 32, a third protective film 33, a first intermediate layer 41, a plurality of terminals 50, and a plurality of bonding layers 60.

In the description of the semiconductor element A10 and a semiconductor device B that will be described later, for example, the direction that is normal to the obverse surface 11A of the main body 11, described later, is referred to as the “first direction z” for convenience. Further, for example, a direction orthogonal to the first direction z is referred to as the “second direction x”. FIG. 1 is a sectional view in which the first direction z and the second direction x define an in-plane direction.

As shown in FIG. 1, the main body 11 includes a semiconductor substrate 111 and a semiconductor layer 112 located on one side of the semiconductor substrate 111 in the first direction z. The main body 11 has an obverse surface 11A and a reverse surface 11B facing away from each other in the first direction z. The semiconductor substrate 111 includes the reverse surface 11B. The semiconductor layer 112 includes the obverse surface 11A. The semiconductor substrate 111 is obtained, for example, from a silicon wafer. Various semiconductor circuits, such as transistors and diodes, are formed on or near the obverse surface 11A of the semiconductor layer 112.

As shown in FIG. 1, the plurality of electrodes 12 are located on the above-mentioned one side of the main body 11 in the first direction z. The electrodes 12 are in contact with the obverse surface 11A of the main body 11. The electrodes 12 electrically conduct to various semiconductor circuits formed in the semiconductor layer 112.

The passivation film 13 covers the obverse surface 11A of the main body 11. The passivation film 13 is in contact with the electrodes 12. Each of the electrodes 12 is exposed from the passivation film 13. The passivation film 13 is a thin film containing silicon dioxide (SiO₂) or silicon nitride (Si₃N₄), or a laminate of such thin films.

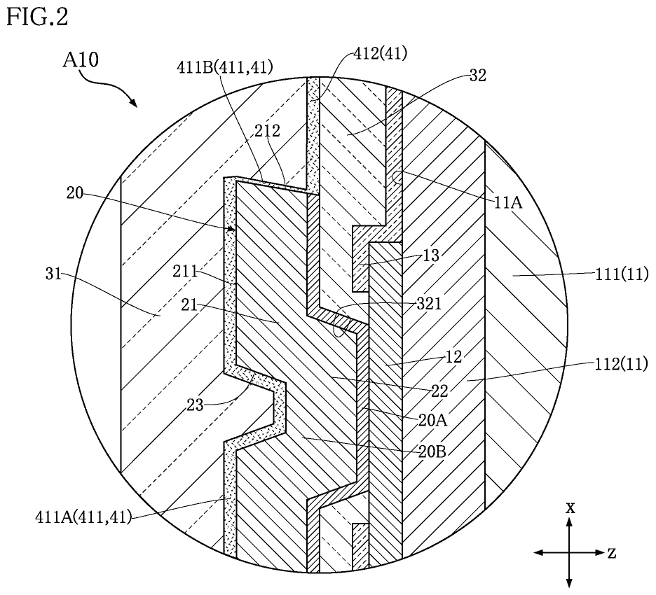

As shown in FIG. 1, the second protective film 32 is located between the main body 11 and the first protective film 31 in the first direction z. The second protective film 32 covers a part of each electrode 12, and the passivation film 13. The second protective film 32 is an insulator containing an organic compound. The second protective film 32 is made of a material containing polyimide. As shown in FIGS. 1 and 2, the second protective film 32 has a plurality of second openings 321 penetrating in the first direction z. The electrodes 12 are individually exposed from the second openings 321.

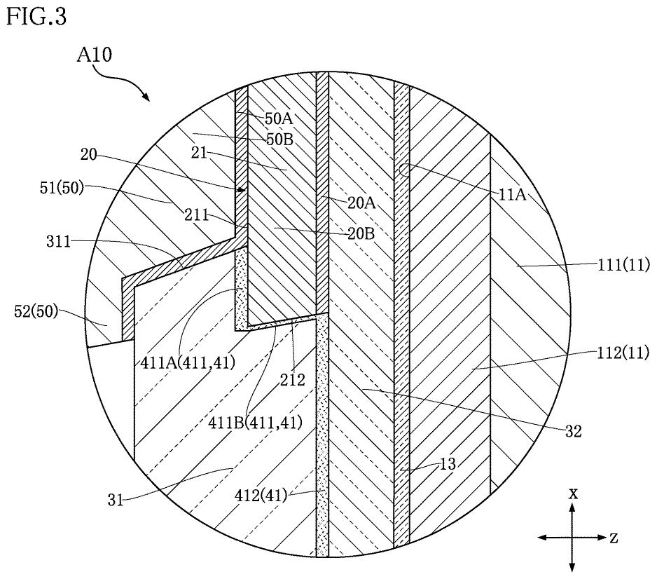

As shown in FIG. 1, the redistribution wirings 20 are located opposite the main body 11 with respect to the electrodes 12 in the first direction z. Each of the redistribution wirings 20 electrically conducts to one of the electrodes 12. As shown in FIGS. 2 and 3, each of the redistribution wirings 20 includes a base layer 20A and a conductive layer 20B. The base layer 20A includes a barrier layer in contact with one of the electrodes 12 and the second protective film 32, and a seed layer laminated on the barrier layer. The barrier layer contains titanium (Ti). The seed layer contains copper (Cu). The conductive layer 20B is laminated on the seed layer of the base layer 20A. The conductive layer 20B contains copper. The dimension of the conductive layer 20B in the first direction z is larger than the dimension of the base layer 20A in the first direction z.

As shown in FIGS. 1 and 2, each of the redistribution wirings 20 has a main portion 21 and a contact portion 22. The contact portion 22 is electrically connected to one of the electrodes 12. The contact portion 22 is accommodated in one of the second openings 321 of the second protective film 32 and in contact with the second protective film 32. The main portion 21 is connected to the contact portion 22. The main portion 21 extends in the second direction x.

As shown in FIGS. 2 and 3, the main portion 21 has a first surface 211 and a second surface 212. The first surface 211 faces away from the main body 11 in the first direction z. That is, the first surface 211 faces the same side as the obverse surface 11A of the main body 11 in the first direction z. The direction normal to the second surface 212 intersects the first direction z. The second surface 212 is inclined relative to the first surface 211. As viewed in the first direction z, the second surface 212 overlaps with the first surface 211.

As shown in FIGS. 1 and 2, the main portion 21 has a recess 23 recessed from the first surface 211. As viewed in the first direction z, the recess 23 overlaps with the contact portion 22.

As shown in FIG. 1, the first protective film 31 is located on the same side as the redistribution wirings 20 with respect to the electrodes 12 in the first direction z. As viewed in the first direction z, the first protective film 31 overlaps with the redistribution wirings 20 and the second protective film 32. The first protective film 31 is an insulator containing an organic compound. The first protective film 31 is made of a material containing polyimide. In the semiconductor element A10, the composition of the first protective film 31 is the same as that of the second protective film 32. The dimension of the first protective film 31 in the first direction z is larger than that of the second protective film 32 in the first direction z. As shown in FIGS. 1 and 3, the first protective film 31 has a plurality of first openings 311 penetrating in the first direction z. The first surface 211 of one of the redistribution wirings 20 is exposed from each of the first openings 311.

As shown in FIG. 2, the first protective film 31 is received in the recess 23 of each of the redistribution wirings 20.

As shown in FIGS. 1 to 3, the first intermediate layer 41 includes first portions 411 located between the redistribution wirings 20 and the first protective film 31, and second portions 412 located between the first protective film 31 and the second protective film 32. The first intermediate layer 41 is an insulator containing an inorganic compound. The first intermediate layer 41 is a thin film containing silicon dioxide or silicon nitride, or a laminate of such thin films. Therefore, the composition of the first intermediate layer 41 includes silicon (Si). Alternatively, the first intermediate layer 41 may be a ceramic material containing aluminum oxide (Al₂O₃) or aluminum nitride (AlN), for example. The adhesion strength of the first protective film 31 to the first intermediate layer 41 is higher than the adhesion strength of the first protective film 31 to the redistribution wirings 20.

As shown in FIGS. 2 and 3, the first portions 411 are in contact with the redistribution wiring 20 and the first protective film 31. Each first portion 411 includes a first region 411A covering the first surface 211 of one of the redistribution wirings 20 and a second region 411B covering the second surface 212 of the redistribution wiring 20. The first region 411A also covers the region of the main portion 21 that defines the recess 23 of a redistribution wiring 20. The dimension of the second region 411B in a direction (the second direction x) orthogonal to the first direction z is smaller than the dimension of the first region 411A in the first direction z.

As shown in FIGS. 2 and 3, each second portion 412 is in contact with the first protective film 31 and the second protective film 32. The second portion 412 is located opposite the first region 411A of the first portion 411 with respect to the second region 411B of the first portion 411 in the first direction z. In the semiconductor element A10, the first protective film 31 is spaced apart from the second protective film 32.

As shown in FIG. 1, the terminals 50 are located opposite the electrodes 12 with respect to the redistribution wirings 20 in the first direction z. Each of the terminals 50 is electrically connected to the main portion 21 of one of the redistribution wirings 20. The terminals 50 are exposed from the first protective film 31.

As shown in FIG. 3, each of the terminals 50 includes a base layer 50A and a conductive layer 50B. The base layer 50A includes a barrier layer in contact with the main portion 21 of one of the redistribution wirings 20 and the first protective film 31, and a seed layer laminated on the barrier layer. The barrier layer contains titanium. The seed layer contains copper. The conductive layer 50B is laminated on the seed layer of the base layer 50A. The conductive layer 50B contains copper. The dimension of the conductive layer 50B in the first direction z is larger than that of the base layer 50A in the first direction z.

As shown in FIGS. 1 and 3, each of the terminals 50 has a base portion 51 and an enlarged portion 52. The base portion 51 is electrically connected to the main portion 21 of one of the redistribution wirings 20. A part of the base portion 51 is accommodated in one of the first openings 311 of the first protective film 31. The base portion 51 is in contact with the first protective film 31. A part of the base portion 51 protrudes from the first protective film 31 in the first direction z. The enlarged portion 52 protrudes outward from one of the first openings 311 as viewed in the first direction z. The enlarged portion 52 is in contact with the first protective film 31.

As shown in FIG. 1, the base portion 51 has a recess 53 that is recessed in the first direction z toward the side that the reverse surface 11B of the main body 11 faces. As viewed in the first direction z, the recess 53 overlaps with one of the first openings 311 of the first protective film 31.

As shown in FIG. 1, the bonding layers 60 are located opposite the redistribution wirings 20 with respect to the terminals 50 in the first direction z. The bonding layers 60 are individually and electrically connected to the terminals 50. The bonding layers 60 are solder. Therefore, the composition of the bonding layers 60 includes tin. The melting point of the bonding layers 60 is lower than that of the terminals 50. Each of the bonding layers 60 is individually received in the recess 53 of one of the terminals 50.

As shown in FIG. 1, the third protective film 33 is located opposite the second protective film 32 with respect to the main body 11 in the first direction z. The third protective film 33 covers the entire reverse surface 11B of the main body 11. The third protective film 33 is an insulator. The third protective film 33 contains, for example, epoxy resin.

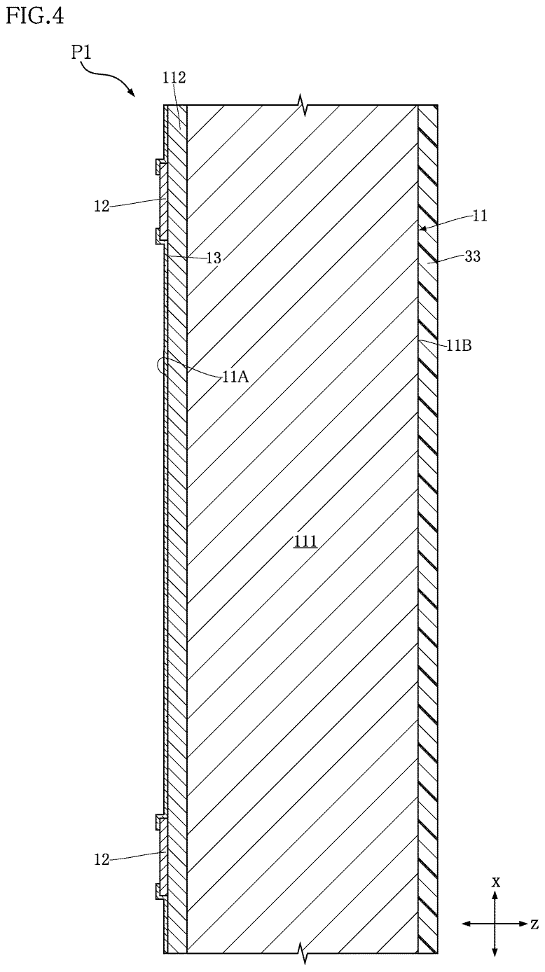

Next, an example of a method for manufacturing the semiconductor element A10 will be described based on FIGS. 4 to 15. Each of FIGS. 4 to 15 corresponds to FIG. 1, which shows the semiconductor element A10.

First, a first step P1 shown in FIG. 4 is performed. In the first step P1, a plurality of electrode 12, a passivation film 13, and a third protective film 33 are formed on the main body 11 on which the semiconductor layer 112 has been formed. Here, the main body 11 corresponds to a part of a silicon wafer. The third protective film 33 is formed by applying a material containing epoxy resin to the reverse surface 11B of the main body 11 and then curing the material.

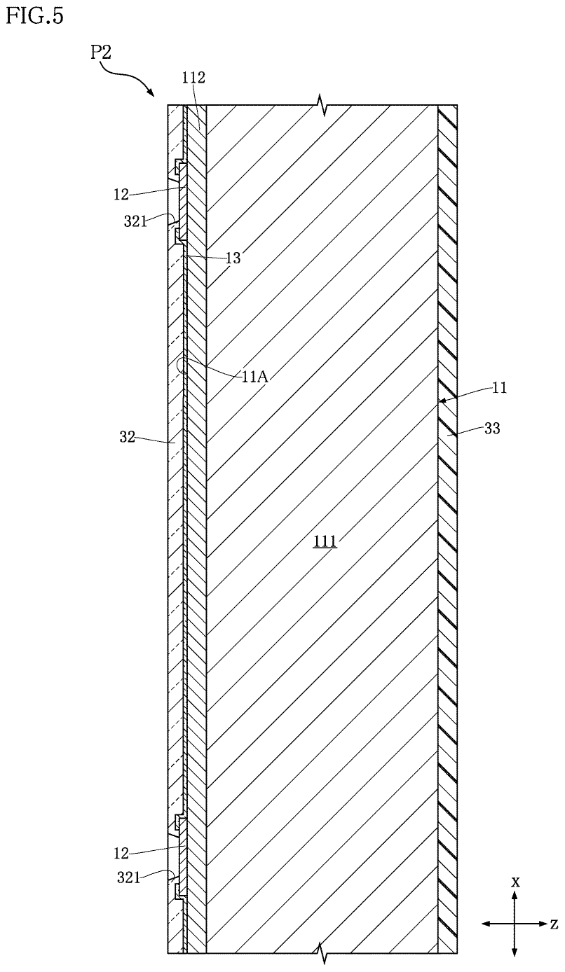

Next, a second step P2 shown in FIG. 5 is performed. In the second step P2, the second protective film 32 that covers the passivation film 13 is formed. The second protective film 32 is formed by applying a material containing photosensitive polyimide to the passivation film 13 and then curing it following lithographic patterning. Through lithographic patterning, a plurality of second openings 321 are formed in the second protective film 32. The electrodes 12 are individually exposed from the second openings 321.

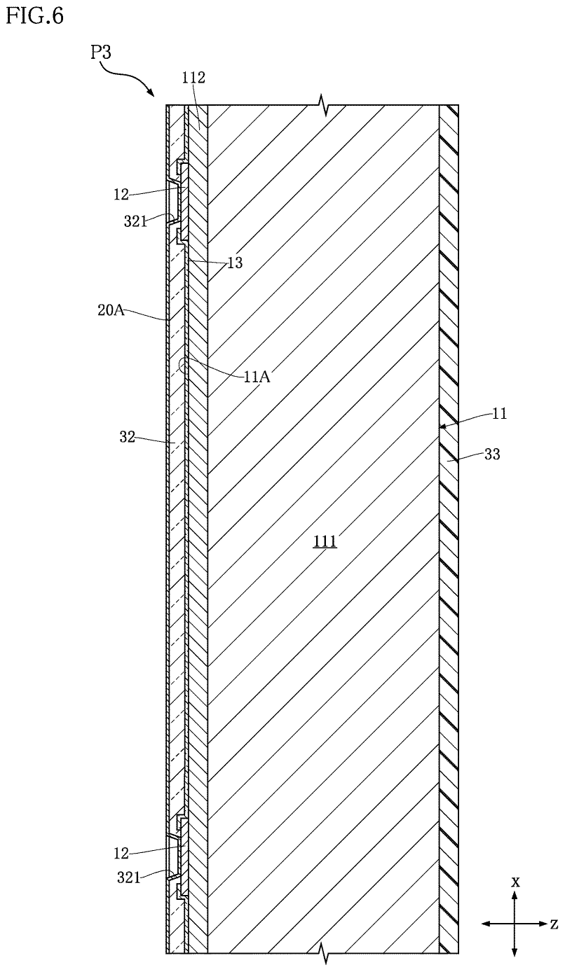

Next, a third step P3 shown in FIG. 6 is performed. In the third step P3, oxides or the like formed on the surfaces of the electrodes 12 are removed by reactive ion etching (RIE), and then the base layer 20A is formed by sputtering. Through this step, the entire second protective film 32 and the electrodes 12 individually exposed through the second openings 321 of the second protective film 32 are covered with the base layer 20A.

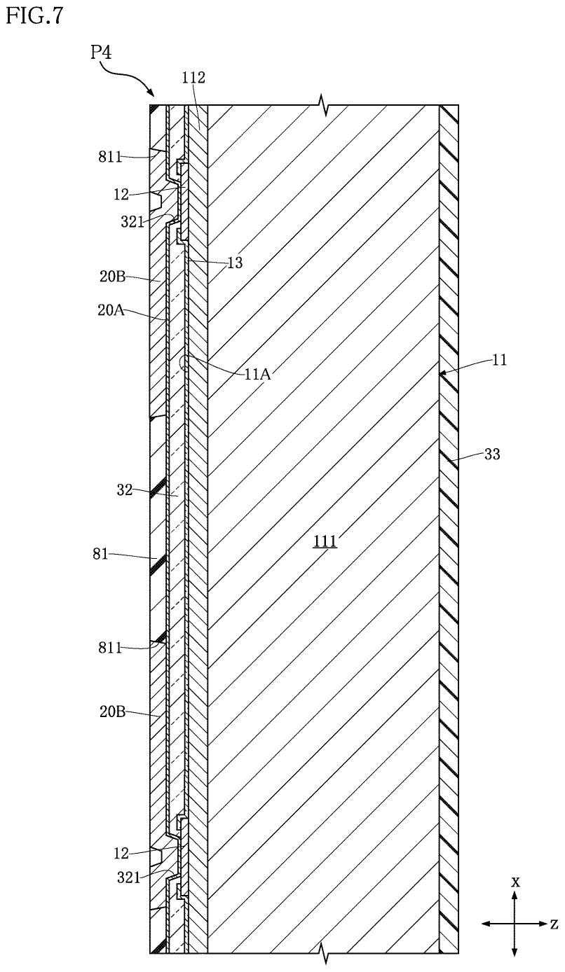

Next, a fourth step P4 shown in FIG. 7 is performed. In the fourth step P4, a plurality of conductive layers 20B are formed. To form the conductive layers 20B, first, a first resist 81 is applied to the base layer 20A, and then lithographic patterning is performed on the first resist 81. As a result, a plurality of openings 811 penetrating in the first direction z are formed in the first resist 81. Next, the conductive layers 20B are deposited by electroplating using the base layer 20A as a conductive path. Thus, the conductive layers 20B individually accommodated in the openings 811 are formed.

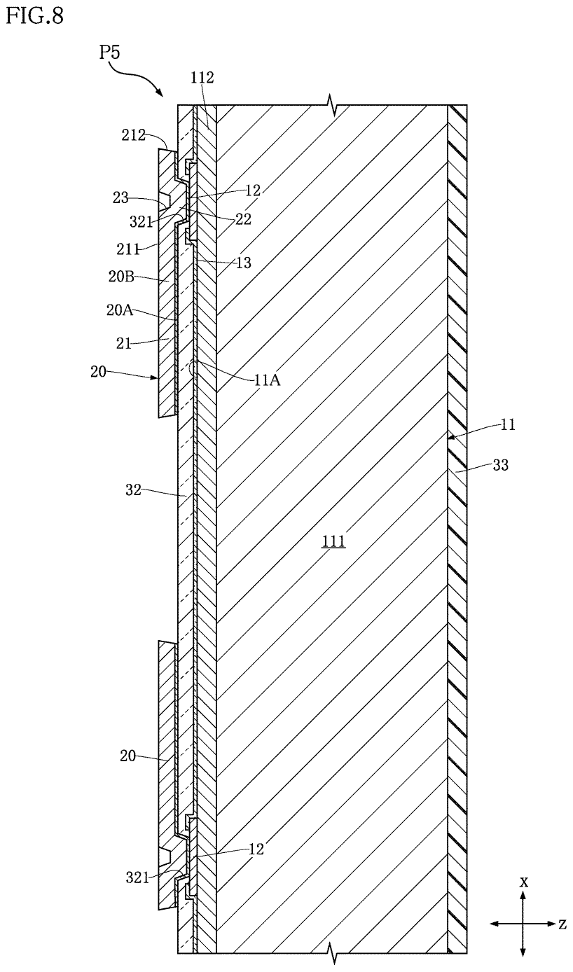

Next, a fifth step P5 shown in FIG. 8 is performed. In the fifth step P5, after the first resist 81 is removed, the regions of the base layer 20A that are exposed from the conductive layers 20B are removed. The removal of the base layer 20A is performed by wet etching using a mixed solution of sulfuric acid (H₂SO₄) and hydrogen peroxide (H₂O₂). Thus, the formation of the redistribution wirings 20 is completed.

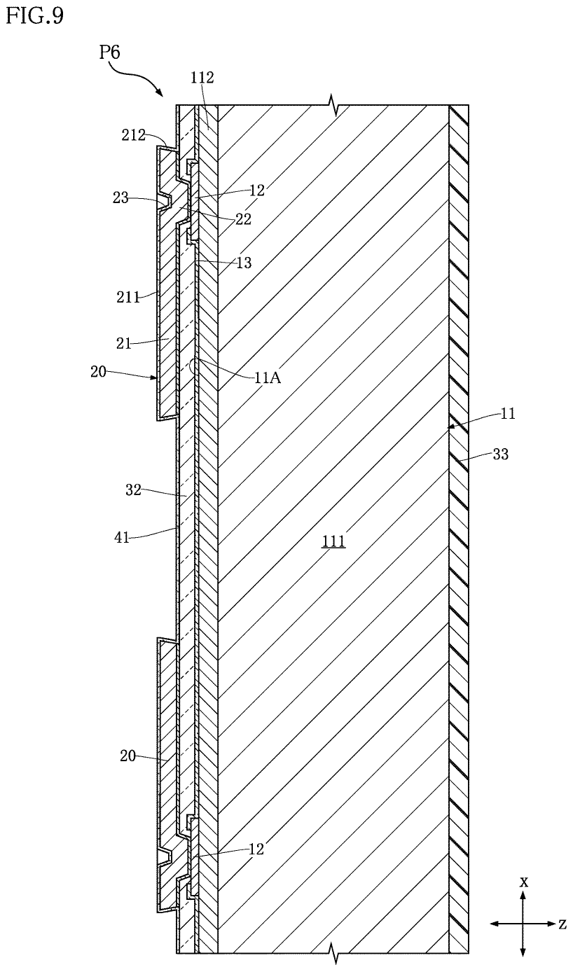

Next, a sixth step P6 shown in FIG. 9 is performed. In the sixth step P6, the first intermediate layer 41 is formed by plasma CVD (Chemical Vapor Deposition) or sputtering. As a result of this step, the entire first protective film 31 and the entirety of each redistribution wiring 20 are covered by the first intermediate layer 41.

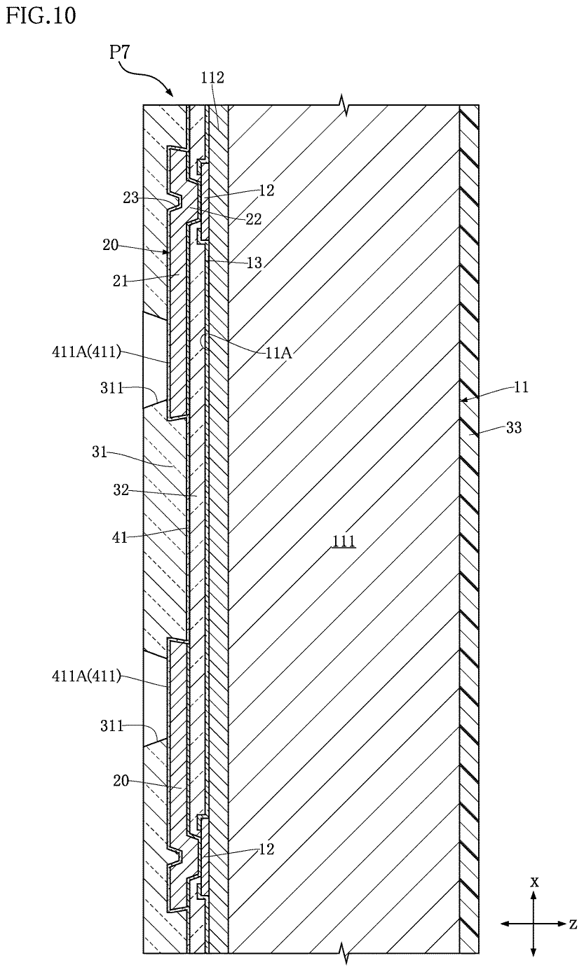

Next, a seventh step P7 shown in FIG. 10 is performed. In the seventh step P7, the first protective film 31 that covers the first intermediate layer 41 is formed. The first protective film 31 is formed by applying a material containing photosensitive polyimide to the first intermediate layer 41 and then curing it following lithographic patterning. Through lithographic patterning, a plurality of first openings 311 are formed in the first protective film 31. The first regions 411A of the first portions 411 of the first intermediate layer 41 are exposed from the first openings 311.

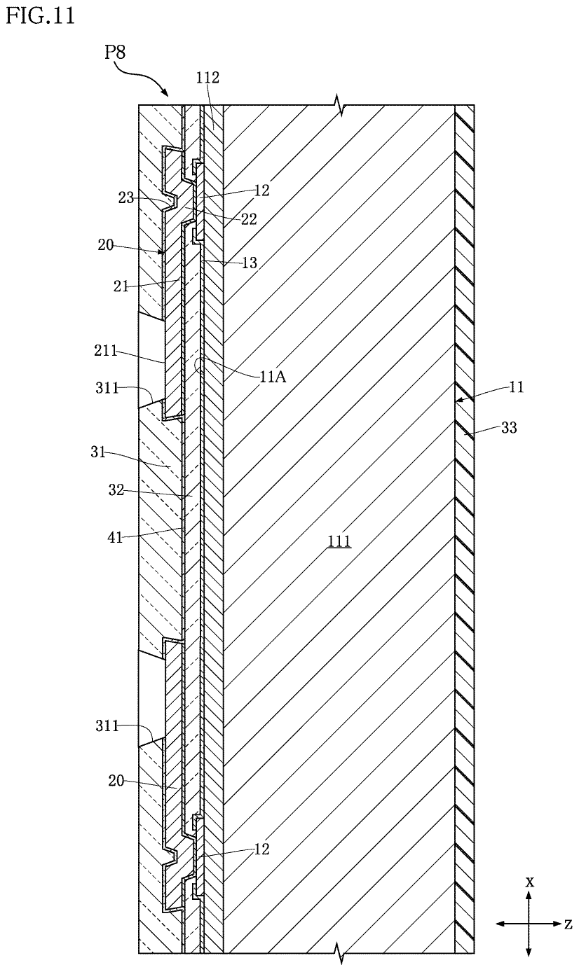

Next, an eighth step P8 shown in FIG. 11 is performed. In the eighth step P8, the first regions 411A of the first portions 411 of the first intermediate layer 41 that are exposed through the first openings 311 of the first protective film 31 are removed by reactive ion etching. As a result of this step, the first surface 211 of one of the redistribution wirings 20 is exposed from each of the first openings 311.

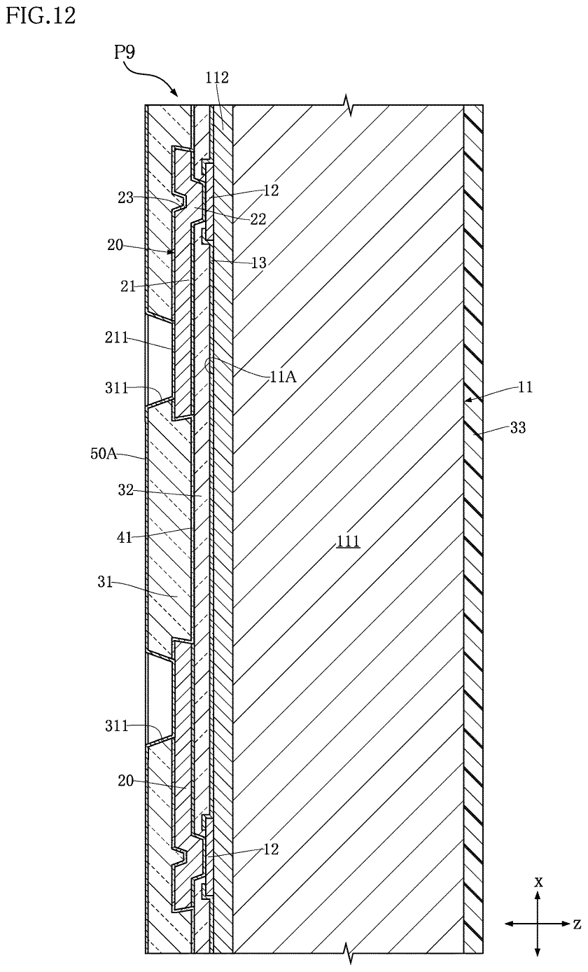

Next, a ninth step P9 shown in FIG. 12 is performed. In the ninth step P9, the base layer 50A is formed by sputtering. As a result of this step, the entire first protective film 31 and the first surfaces 211 of the redistribution wirings 20 exposed through the first openings 311 of the first protective film 31 are covered by the base layer 50A.

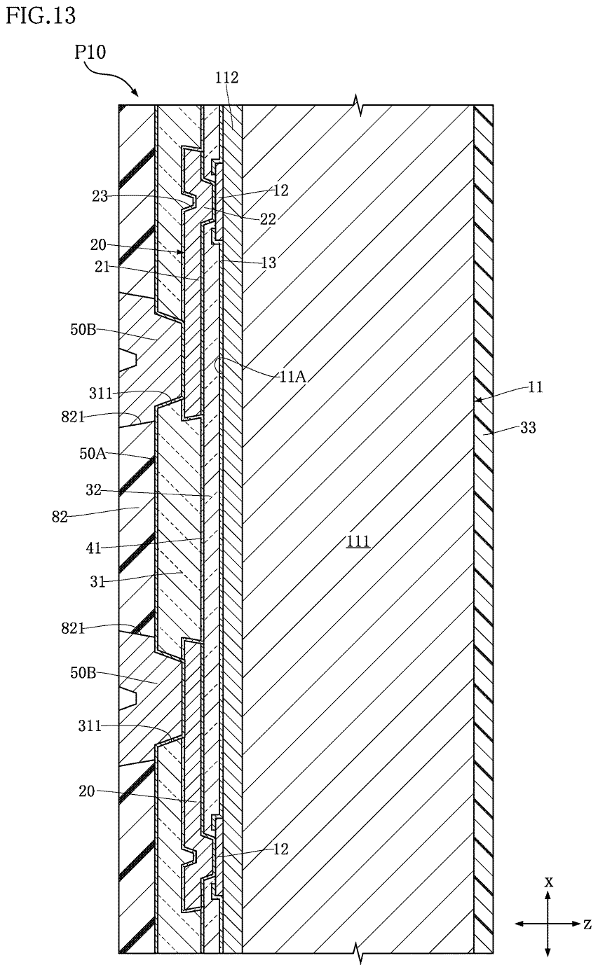

Next, a tenth step P10 shown in FIG. 13 is performed. In the tenth step P10, a plurality of conductive layers 50B are formed. To form the conductive layers 50B, first, a second resist 82 is applied to the base layer 50A, and then lithographic patterning is performed on the second resist 82. As a result, a plurality of openings 821 penetrating in the first direction z are formed in the second resist 82. Next, the conductive layers 50B are deposited by electroplating using the base layer 50A as a conductive path. Thus, the conductive layers 50B individually accommodated in the openings 821 are formed.

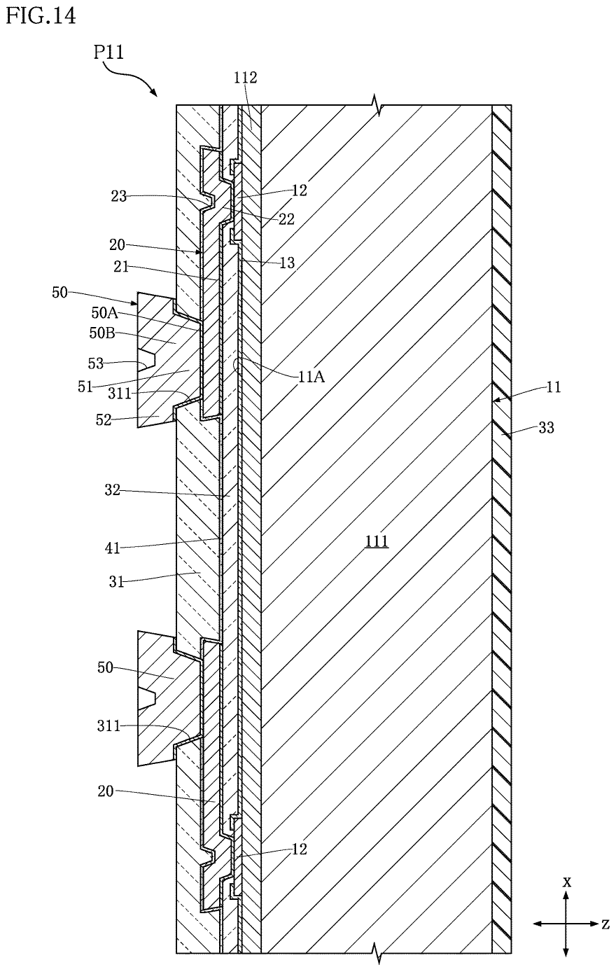

Next, an eleventh step P11 shown in FIG. 14 is performed. In the eleventh step P11, after the second resist 82 is removed, the regions of the base layer 50A that are exposed from the conductive layers 50B are removed. The removal of the base layer 50A is performed by wet etching using a mixed solution of sulfuric acid and hydrogen peroxide. Thus, the formation of the terminals 50 is completed.

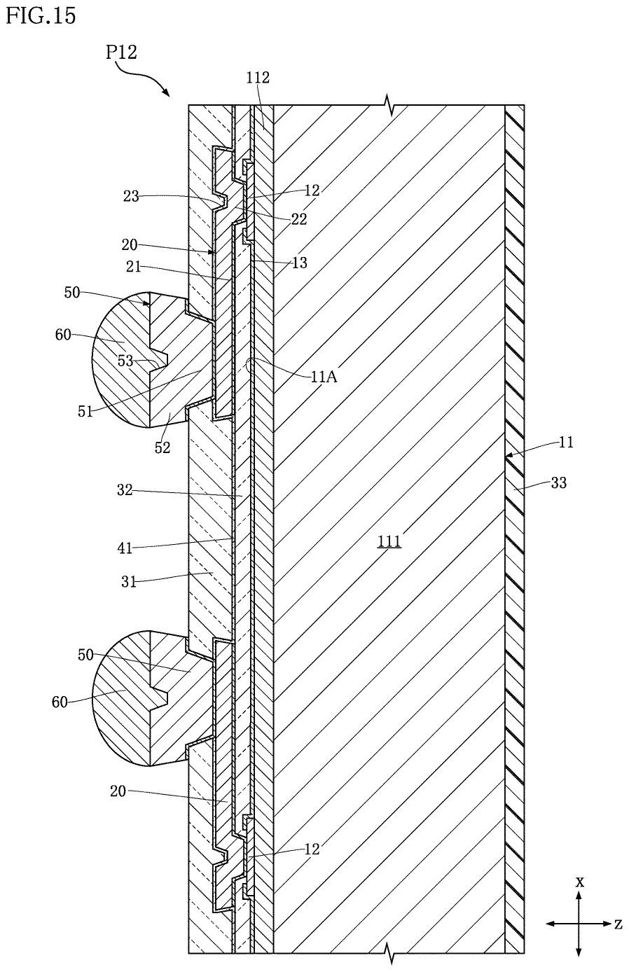

Next, a twelfth step P12 shown in FIG. 15 is performed. In the twelfth step P12, a plurality of bonding layers 60 are formed. To form the bonding layers 60, a material containing solder is first disposed on the terminals 50. Then, the material is melted by reflow. Finally, the melted material is solidified. Thus, bonding layers 60 individually applied to the terminals 50 are formed.

Finally, the main body 11, which constitutes a part of a silicon wafer, is divided into individual pieces by blade dicing, for example. Through the above steps, the semiconductor element A10 is obtained.

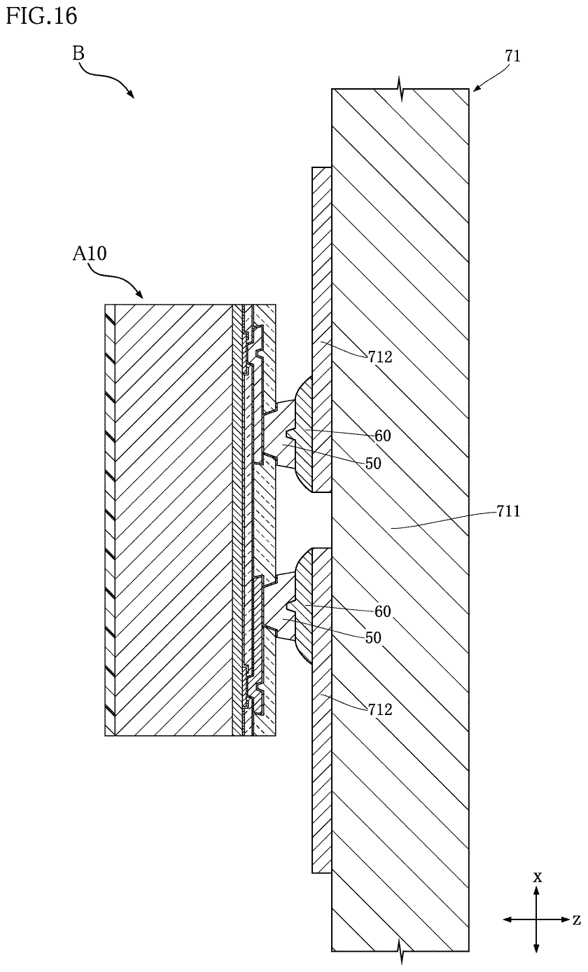

Next, a semiconductor device B incorporating the semiconductor element A10 will be described based on FIG. 16.

As shown in FIG. 16, the semiconductor device B includes the semiconductor element A10 and a base member 71. The semiconductor element A10 is mounted on the base member 71. The base member 71 includes a substrate 711 and conductive portions 712. The substrate 711 is an insulator. The conductive portions 712 contain copper, for example. The terminals 50 of the semiconductor element A10 are conductively bonded to the conductive portions 712 via the bonding layers 60.

In the semiconductor device B, the base member 71 is a wiring board. Alternatively, the base member 71 may include only the conductive portions 712 serving as leads. The base member 71 may include an external terminal located opposite the conductive portions 712 with respect to the substrate 711 in the first direction z. In the semiconductor device B, at least a part of the semiconductor element A10 may be covered with sealing resin such as underfill.

Next, the effects of the semiconductor element A10 will be described.

The semiconductor element A10 includes the main body 11, the electrode 12, the redistribution wiring 20, the first protective film 31, and the first intermediate layer 41. The first intermediate layer 41 includes the first portion 411 located between the redistribution wiring 20 and the first protective film 31. The first portion 411 is in contact with the first protective film 31. The first intermediate layer 41 is an insulator containing an inorganic compound. The adhesion strength of the first protective film 31 to the first intermediate layer 41 is higher than the adhesion strength of the first protective film 31 to the redistribution wiring 20. With this configuration, the first protective film 31 is firmly bonded to the first intermediate layer 41 at the interface between the redistribution wiring 20 and the first protective film 31. The semiconductor element A10 having such a configuration can suppress delamination of the first protective film 31 from the redistribution wiring 20 using a simpler structure.

The first portion 411 of the first intermediate layer 41 is in contact with the redistribution wiring 20. This configuration prevents unintended delamination of the first intermediate layer 41 from the redistribution wiring 20.

The redistribution wiring 20 has the first surface 211 and the second surface 212. The second surface 212 is inclined relative to the first surface 211. As viewed in the first direction z, the second surface 212 overlaps with the first surface 211. The first portion 411 of the first intermediate layer 41 covers the first surface 211 and the second surface 212. With this configuration, a reaction force in the first direction z acts from the redistribution wiring 20 toward the first protective film 31 at the interface between the second surface 212 and the first protective film 31. This prevents delamination of the first protective film 31 from the redistribution wiring 20 that starts from the interface between the second surface 212 and the first protective film 31.

The semiconductor element A10 further includes a second protective film 32 located between the main body 11 and the first protective film 31. The second protective film 32 covers a part of the electrode 12. With this configuration, leakage current from the electrode 12 caused by the arrangement of the redistribution wiring 20 can be suppressed.

The first intermediate layer 41 includes a second portion 412 located between the first protective film 31 and the second protective film 32. The second portion 412 is in contact with the first protective film 31 and the second protective film 32. With this configuration, delamination of t he first protective film 31 from the second protective film 32 can be suppressed even when the affinity between the first protective film 31 and the second protective film 32 is relatively low.

The semiconductor element A10 further includes the terminal 50. A part of the terminal 50 is accommodated in the first opening 311 of the first protective film 31. The terminal 50 has the enlarged portion 52 protruding outward from the first opening 311 as viewed in the first direction z. This configuration increases the bonding area between the terminal 50 and the conductive portion 712 of the base member 71 in the semiconductor device B.

The semiconductor element A10 further includes the bonding layer 60 located opposite the redistribution wiring 20 with respect to the terminal 50. The bonding layer 60 is electrically connected to the terminal 50. The melting point of the bonding layer 60 is lower than that of the terminal 50. With this configuration, the terminal 50 can be easily conductively bonded to the conductive portion 712 of the base member 71 in the semiconductor device B.

The bonding layer 60 is received in the recess 53 of the terminal 50. With this configuration, in the semiconductor device B, the bonding layer 60 exerts an anchoring effect on the terminal 50. This improves the bonding strength to the conductive portion 712 of the base member 71.

The semiconductor element A10 further includes a third protective film 33 located opposite the second protective film 32 with respect to the main body 11. The third protective film 33 covers the main body 11. With this configuration, warping of the main body 11 around an axis orthogonal to the first direction z can be reduced during the formation processes of the redistribution wiring 20, the first protective film 31, the second protective film 32, the first intermediate layer 41, and the terminal 50 in the manufacture of the semiconductor element A10.

### Second Embodiment

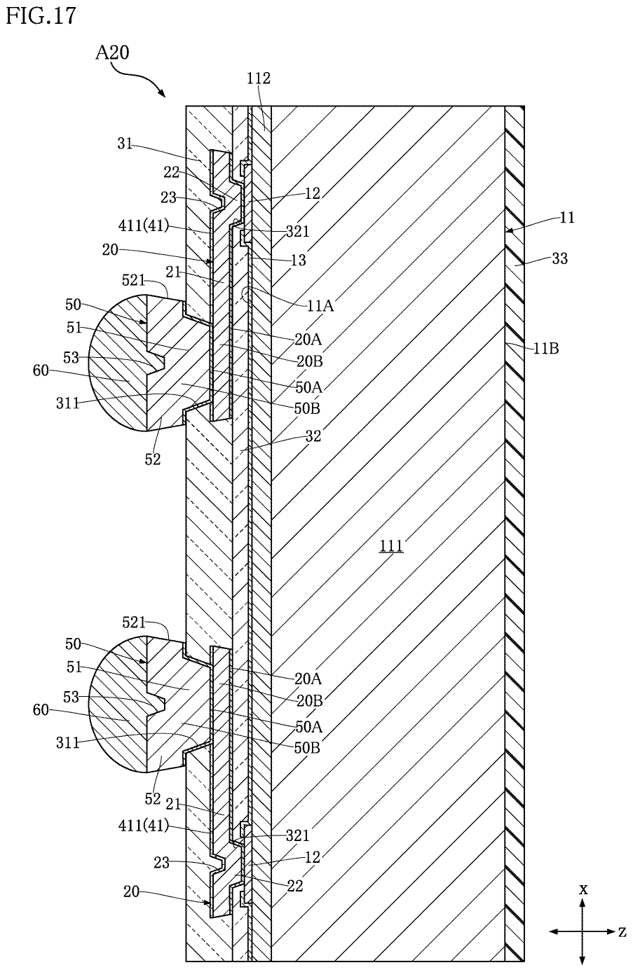

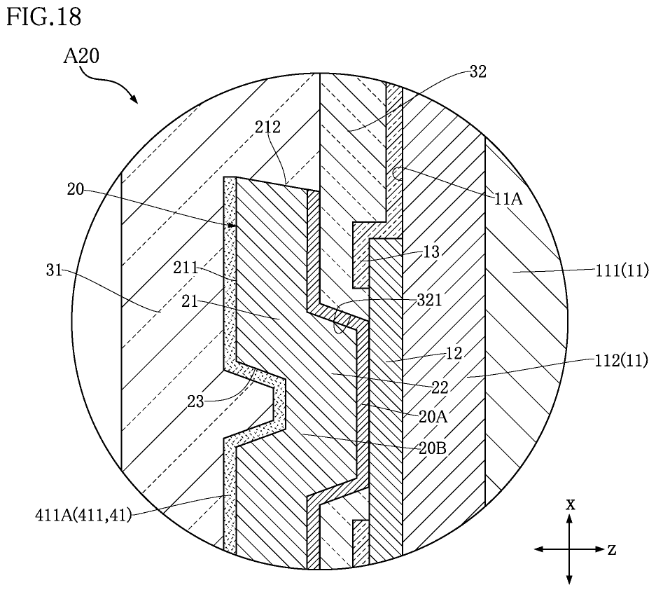

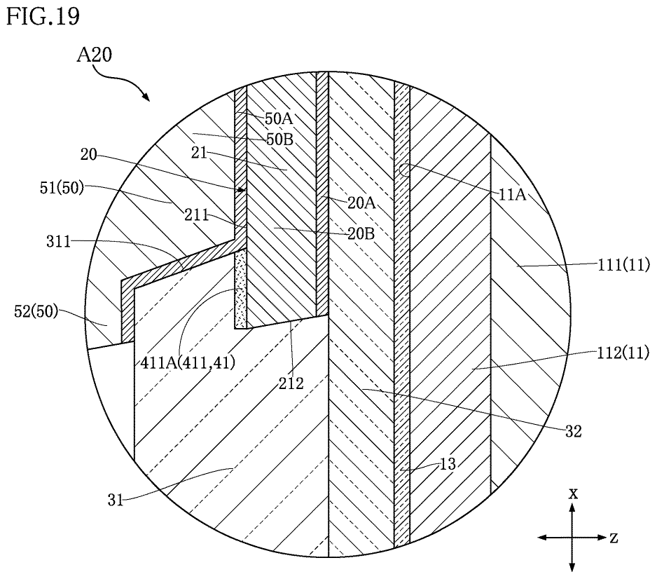

A semiconductor element A20 according to a second embodiment of the present disclosure will be described based on FIGS. 17 to 19. In these figures, the elements that are identical or similar to those of the semiconductor element A10 described above are denoted by the same reference signs, and the descriptions thereof are omitted. FIG. 17 corresponds to FIG. 1, which shows the semiconductor element A10.

The semiconductor element A20 differs from the semiconductor element A10 in the configuration of the first intermediate layer 41.

As shown in FIGS. 17 to 19, the first intermediate layer 41 includes only the first region 411A of the first portion 411. Thus, the first intermediate layer 41 does not include the second region 411B of the first portion 411 and the second portion 412. The second surface 212 of each of the redistribution wirings 20 is in contact with the first protective film 31. The first protective film 31 is in contact with the second protective film 32.

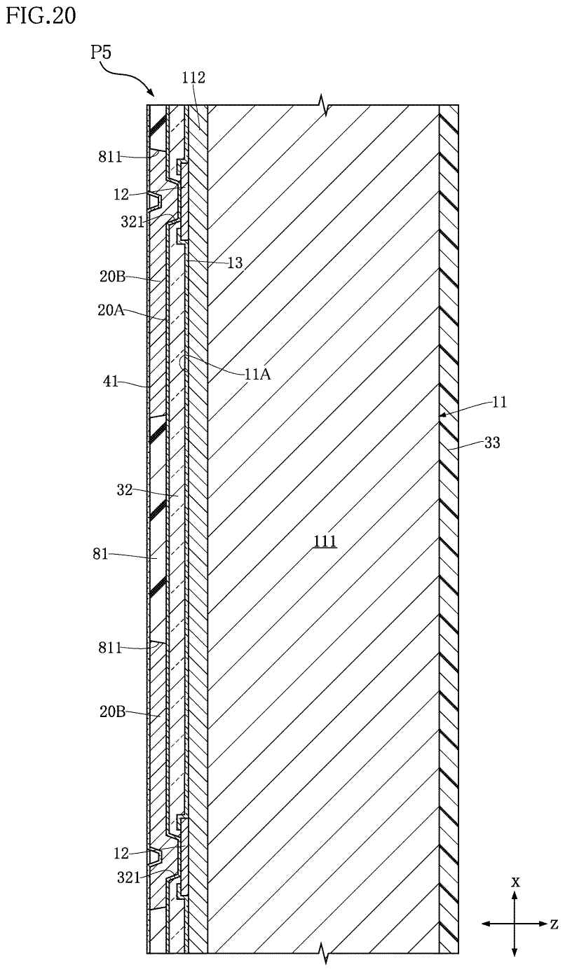

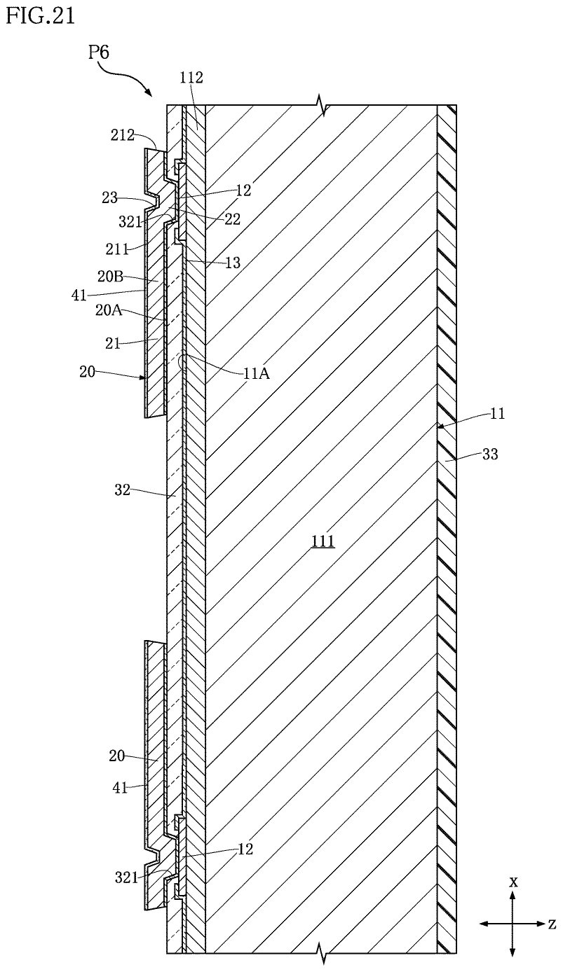

Next, an example of a method for manufacturing the semiconductor element A20 will be described based on FIGS. 20 to 21. Each of FIGS. 20 and 21 corresponds to FIG. 17, which shows the semiconductor element A20.

In the manufacturing process for the semiconductor element A20, the first step P1 through the fourth step P4 and the seventh step P7 through the twelfth step P12 are the same as those in the manufacturing process for the semiconductor element A10 described above. Therefore, in the description of the manufacturing method for the semiconductor element A20, only the fifth step P5 and the sixth step P6 will be explained.

After the fourth step P4 (see FIG. 7) is completed, the fifth step P5 shown in FIG. 20 is performed. In the fifth step P5, the first intermediate layer 41 is formed by plasma CVD or sputtering. As a result of this step, the entire surface of the first resist 81 and the entire surfaces of the conductive layers 20B that are exposed through the openings 811 are covered with the first intermediate layer 41.

Next, a sixth step P6 shown in FIG. 21 is performed. In the sixth step P6, after the first resist 81 is removed, the regions of the base layer 20A that are exposed from the conductive layers 20B are removed. By removing the first resist 81, the region of the first intermediate layer 41 that covers the entire surface of the first resist 81 is removed by lift-off. The removal of the base layer 20A is performed by wet etching using a mixed solution of sulfuric acid and hydrogen peroxide. Thus, the formation of the redistribution wirings 20 is completed. In the resulting structure, the second surface 212 of each of the redistribution wirings 20 and the surface of the second protective film 32 are exposed from the first intermediate layer 41.

Next, the effects of the semiconductor element A20 will be described.

The semiconductor element A20 includes the main body 11, the electrode 12, the redistribution wiring 20, the first protective film 31, and the first intermediate layer 41. The first intermediate layer 41 includes the first portion 411 located between the redistribution wiring 20 and the first protective film 31. The first portion 411 is in contact with the first protective film 31. The first intermediate layer 41 is an insulator containing an inorganic compound. The adhesion strength of the first protective film 31 to the first intermediate layer 41 is higher than the adhesion strength of the first protective film 31 to the redistribution wiring 20. The semiconductor element A20 having such a configuration can also suppress delamination of the first protective film 31 from the redistribution wiring 20 using a simpler structure. Further, the semiconductor element A20 has a configuration in common with the semiconductor element A10, thereby achieving the same effect as the semiconductor element A10.

In the semiconductor element A20, the first protective film 31 is in contact with the second protective film 32. The composition of the second protective film 32 is the same as that of the first protective film 31. With this configuration again, delamination of the first protective film 31 from the second protective film 32 can be suppressed because of the relatively high affinity between the first protective film 31 and the second protective film 32.

### Third Embodiment

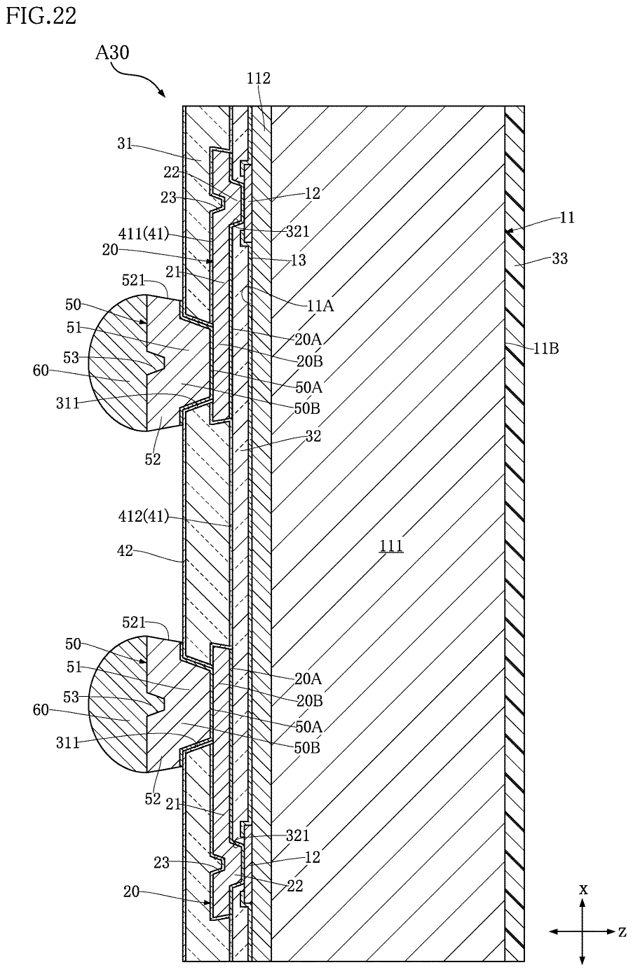

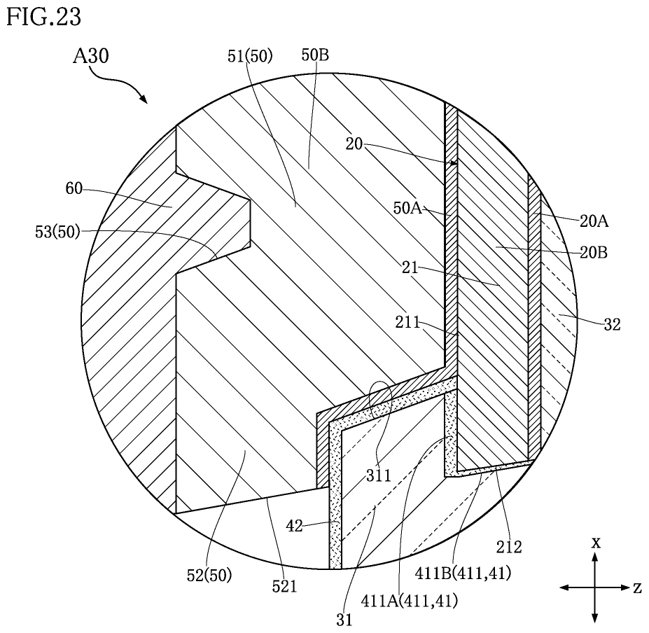

A semiconductor element A30 according to a third embodiment of the present disclosure will be described based on FIGS. 22 and 23. In these figures, the elements that are identical or similar to those of the semiconductor element A10 described above are denoted by the same reference signs, and the descriptions thereof are omitted. FIG. 22 corresponds to FIG. 1, which shows the semiconductor element A10.

The semiconductor element A30 differs from the semiconductor element A10 in that it further includes a second intermediate layer 42.

As shown in FIGS. 22 and 23, the second intermediate layer 42 includes portions each located between the first protective film 31 and the enlarged portion 52 of one of the terminals 50. The second intermediate layer 42 is an insulator containing an inorganic compound. The composition of the second intermediate layer 42 is the same as that of the first intermediate layer 41. As a result, the adhesion strength of the first protective film 31 to the second intermediate layer 42 is higher than the adhesion strength of the first protective film 31 to each of the terminals 50. The second intermediate layer 42 is in contact with the first protective film 31 and the enlarged portion 52 of each of the terminals 50.

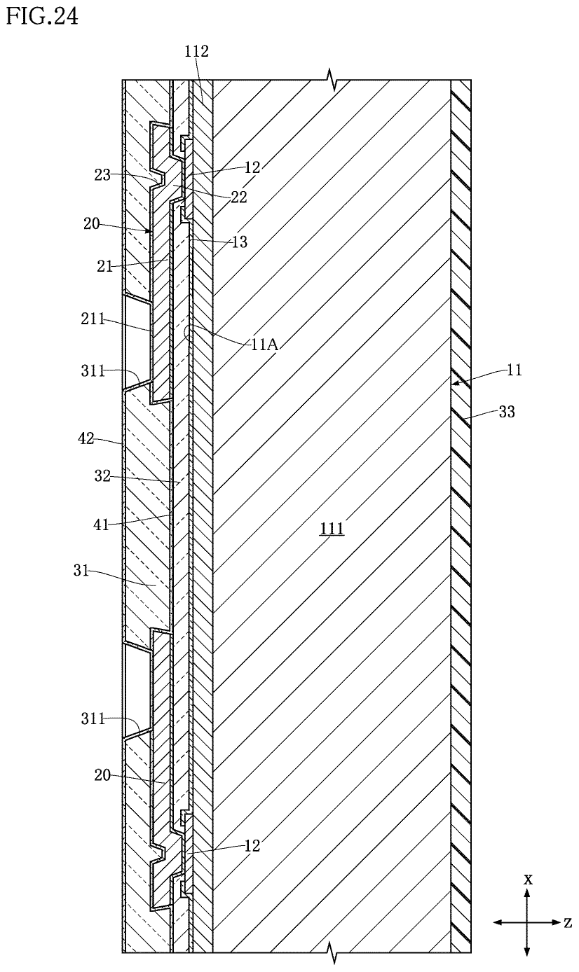

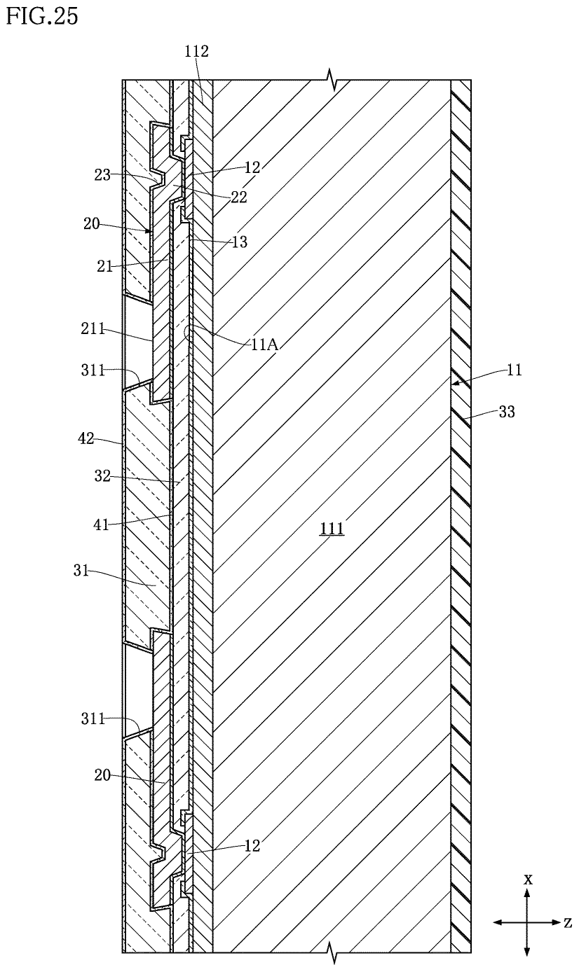

Next, an example of a method for manufacturing the semiconductor element A30 will be described based on FIGS. 24 and 25. Each of FIGS. 24 and 25 corresponds to FIG. 22, which shows the semiconductor element A30.

The manufacturing process for the semiconductor element A30 further includes the step for forming a second intermediate layer 42 between the eighth step P8 and the ninth step P9, in addition to the above-described steps of the manufacturing process for the semiconductor element A10. Therefore, in the description of the manufacturing method for the semiconductor element A30, only the step for forming the second intermediate layer 42 will be described.

After the eighth step P8 (see FIG. 11) is completed, a second intermediate layer 42 is formed as shown in FIG. 24. The second intermediate layer 42 is formed by plasma CVD or sputtering. As a result of this step, the entire surface of the first protective film 31 and the first surfaces 211 of the redistribution wirings 20 exposed through the first openings 311 of the first protective film 31 are covered with the second intermediate layer 42.

Next, as shown in FIG. 25, the portions of the second intermediate layer 42 that are exposed through the first openings 311 of the first protective film 31 are removed. The removal of the second intermediate layer 42 is performed by reactive ion etching. As a result of this step, the first surface 211 of one of the redistribution wirings 20 is exposed from each of the first openings 311. Thus, formation of the second intermediate layer 42 is completed.

Next, the effects of the semiconductor element A30 will be described.

The semiconductor element A30 includes the main body 11, the electrode 12, the redistribution wiring 20, the first protective film 31, and the first intermediate layer 41. The first intermediate layer 41 includes the first portion 411 located between the redistribution wiring 20 and the first protective film 31. The first portion 411 is in contact with the first protective film 31. The first intermediate layer 41 is an insulator containing an inorganic compound. The adhesion strength of the first protective film 31 to the first intermediate layer 41 is higher than the adhesion strength of the first protective film 31 to the redistribution wiring 20. The semiconductor element A30 having such a configuration can also suppress delamination of the first protective film 31 from the redistribution wiring 20 using a simpler structure. Further, the semiconductor element A30 has a configuration in common with the semiconductor element A10, thereby achieving the same effect as the semiconductor element A10.

The semiconductor element A30 further includes the second intermediate layer 42 that includes a portion located between the first protective film 31 and the enlarged portion 52 of a terminal 50. The composition of the second intermediate layer 42 is the same as that of the first intermediate layer 41. The second intermediate layer 42 is in contact with the first protective film 31 and the enlarged portion 52. With this configuration, even when the area of the terminal 50 is increased as viewed in the first direction z, the first protective film 31 is adhered to the second intermediate layer 42 at the interface between the enlarged portion 52 and the first protective film 31. The adhesion between the first protective film 31 and the second intermediate layer 42 is relatively strong. This suppresses delamination of the first protective film 31 from the terminal 50.

### Fourth Embodiment

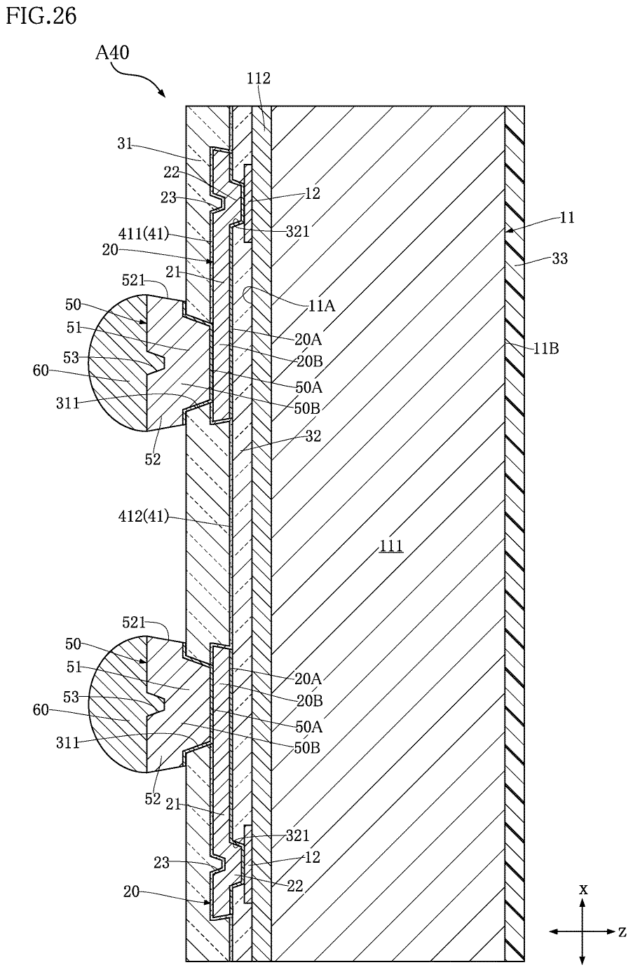

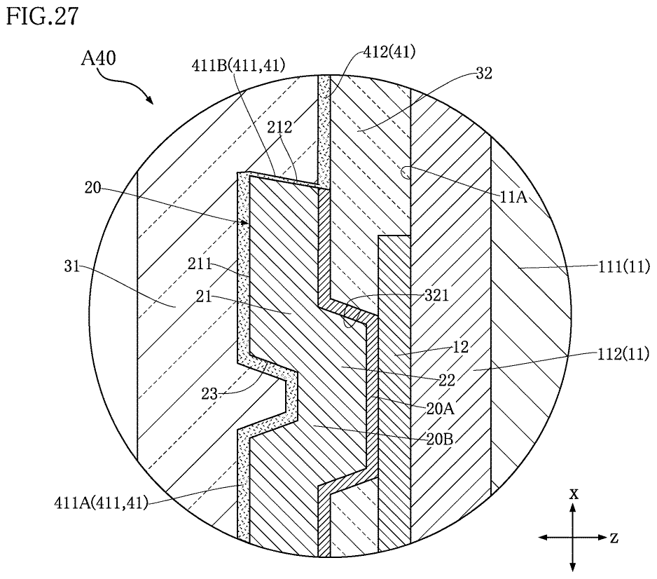

A semiconductor element A40 according to a fourth embodiment of the present disclosure will be described based on FIGS. 26 and 27. In these figures, the elements that are identical or similar to those of the semiconductor element A10 described above are denoted by the same reference signs, and the descriptions thereof are omitted. FIG. 26 corresponds to FIG. 1, which shows the semiconductor element A10.

The semiconductor element A40 differs from the semiconductor element A10 in that it does not include the passivation film 13.

As shown in FIGS. 26 and 27, the semiconductor element A40 does not include the passivation film 13. The second protective film 32 covers the obverse surface 11A of the main body 11.

Next, the effects of the semiconductor element A40 will be described.

The semiconductor element A40 includes the main body 11, the electrode 12, the redistribution wiring 20, the first protective film 31, and the first intermediate layer 41. The first intermediate layer 41 includes the first portion 411 located between the redistribution wiring 20 and the first protective film 31. The first portion 411 is in contact with the first protective film 31. The first intermediate layer 41 is an insulator containing an inorganic compound. The adhesion strength of the first protective film 31 to the first intermediate layer 41 is higher than the adhesion strength of the first protective film 31 to the redistribution wiring 20. The semiconductor element A40 having such a configuration can suppress delamination of the first protective film 31 from the redistribution wiring 20 using a simpler structure. Further, the semiconductor element A40 has a configuration in common with the semiconductor element A10, thereby achieving the same effect as the semiconductor element A10.

In the semiconductor element A40, the second protective film 32 covers the obverse surface 11A of the main body 11. With this configuration, the semiconductor layer 112 of the main body 11 is protected and insulated by the second protective film 32, even in the absence of the passivation film 13.

The present disclosure is not limited to the above-described embodiments. Various modifications in design may be made freely in the specific structure of each part of the present disclosure.

The present disclosure includes the embodiments described in the following clauses.

### Clause 1.

A semiconductor element comprising:
a main body including a semiconductor layer;
an electrode located on one side of the main body in a first direction and electrically conducting to the semiconductor layer;
a redistribution wiring located opposite the main body with respect to the electrode and electrically conducting to the electrode;
a first protective film located on a same side as the redistribution wiring with respect to the electrode and overlapping with the redistribution wiring as viewed in the first direction; and
a first intermediate layer including a first portion located between the redistribution wiring and the first protective film, wherein
the first portion is in contact with the first protective film,
the first intermediate layer is an insulator and contains an inorganic compound, and
an adhesion strength of the first protective film to the first intermediate layer is higher than an adhesion strength of the first protective film to the redistribution wiring.

### Clause 2.

The semiconductor element according to clause 1, wherein the first portion is in contact with the redistribution wiring.

### Clause 3.

The semiconductor element according to clause 2, wherein the first protective film contains an organic compound.

### Clause 4.

The semiconductor element according to clause 3, wherein a composition of the first intermediate layer includes silicon.

### Clause 5.

The semiconductor element according to clause 3, wherein the redistribution wiring includes a first surface that faces away from the main body in the first direction, and
the first portion covers the first surface.

### Clause 6.

The semiconductor element according to clause 5, wherein the redistribution wiring includes a second surface,
a direction normal to the second surface intersects the first direction, and
the first portion covers the second surface.

### Clause 7.

The semiconductor element according to clause 6, wherein the second surface is inclined relative to the first surface.

### Clause 8.

The semiconductor element according to clause 7, wherein the second surface overlaps with the first surface as viewed in the first direction.

### Clause 9.

The semiconductor element according to clause 8, wherein the first portion includes a first region covering the first surface and a second region covering the second surface, and
a dimension of the second region in a direction orthogonal to the first direction is smaller than a dimension of the first region in the first direction.

### Clause 10.

The semiconductor element according to any one of clauses 5 to 9, further comprising a second protective film, wherein
the second protective film is located between the main body and the first protective film, and
the second protective film covers a part of the electrode.

### Clause 11.

The semiconductor element according to clause 10, wherein a composition of the second protective film is the same as a composition of the first protective film.

### Clause 12.

The semiconductor element according to clause 11, wherein the first intermediate layer includes a second portion located between the first protective film and the second protective film, and
the second portion is in contact with the first protective film and the second protective film

### Clause 13.

The semiconductor element according to clause 11, wherein the first protective film is in contact with the second protective film.

### Clause 14.

The semiconductor element according to clause 12, wherein the redistribution wiring includes a main portion including the first surface and a contact portion connected to the main portion, and
the contact portion is electrically connected to the electrode and in contact with the second protective film.

Clause 15.

The semiconductor element according to clause 14, further comprising a terminal electrically connected to the redistribution wiring, wherein
the terminal is located opposite the electrode with respect to the redistribution wiring, and
the terminal is exposed from the first protective film.

### Clause 16.

The semiconductor element according to clause 15, wherein the first protective film includes a first opening penetrating in the first direction and exposing the redistribution wiring,
a part of the terminal is accommodated in the first opening, and
the terminal includes an enlarged portion protruding outward from the first opening as viewed in the first direction.

### Clause 17.

The semiconductor element according to clause 16, further comprising a second intermediate layer that includes a portion located between the first protective film and the enlarged portion, wherein
a composition of the second intermediate layer is the same as a composition of the first intermediate layer, and
the second intermediate layer is in contact with the first protective film and the enlarged portion.

### Clause 18.

The semiconductor element according to clause 16, wherein the enlarged portion is in contact with the first protective film.

### Clause 19.

The semiconductor element according to clause 16, further comprising a third protective film located opposite the second protective film with respect to the main body, and
the third protective film covers the main body.

### Clause 20.

A semiconductor device comprising:
the semiconductor element as set forth in clause 15; and
a base member including a conductive portion, wherein
the semiconductor element is mounted on the base member, and
the terminal is conductively bonded to the conductive portion.

### Clause 21.

The semiconductor element according to clause 3, wherein the first protective film contains polyimide.

### Clause 22.

The semiconductor element according to clause 3, wherein the first intermediate layer contains aluminum oxide.

### Clause 23.

The semiconductor element according to clause 4, wherein the first intermediate layer contains at least one of silicon dioxide and silicon nitride.

### Clause 24.

The semiconductor element according to clause 10, wherein the second protective film covers the main body.

### Clause 25.

The semiconductor element according to clause 11, wherein each of the first protective film and the second protective film contains polyimide.

### Clause 26.

The semiconductor element according to clause 24, wherein a dimension of the second protective film in the first direction is smaller than a dimension of the first protective film in the first direction.

### Clause 27.

The semiconductor element according to clause 12, wherein the first protective film is spaced apart from the second protective film.

### Clause 28.

The semiconductor element according to clause 14, wherein the main portion includes a recess that is recessed from the first surface, and
the first protective film is received in the recess.

### Clause 29.

The semiconductor element according to clause 16, wherein the second protective film includes a second opening penetrating in the first direction and exposing the electrode, and
the contact portion is accommodated in the second opening.

### Clause 30.

The semiconductor element according to clause 16, further comprising a bonding layer electrically connected to the terminal, wherein
the bonding layer is located opposite the redistribution wiring with respect to the terminal, and
a melting point of the bonding layer is lower than a melting point of the terminal.

### REFERENCE NUMERALS

A10 to A40: Semiconductor element B: Semiconductor device
11: Main body 11A: Obverse surface
11B: Reverse surface 111: Semiconductor substrate
112: Semiconductor layer 12: Electrode
13: Passivation film 20: Redistribution wiring
20A: Base layer 20B: Conductive layer
21: Main portion 211: First surface
212: Second surface 22: Contact portion
23: Recess 31: First protective film
311: First opening 32: Second protective film
321: Second opening 33: Third protective film
41: First intermediate layer 411: First portion
411A, 411B: First region, Second region 412: Second portion
42: Second intermediate layer 50: Terminal
51: Base portion 52: Enlarged portion 53: Recess
60: Bonding layer 71: Base member
711: Substrate 712: Conductive portion
81: First resist 811: Opening
82: Second resist 821: Opening
P1 to P12: First step to twelfth step z: First direction
x: Second direction

1. A semiconductor element comprising:
a main body including a semiconductor layer;
an electrode located on one side of the main body in a first direction and electrically conducting to the semiconductor layer;
a redistribution wiring located opposite the main body with respect to the electrode and electrically conducting to the electrode;
a first protective film located on a same side as the redistribution wiring with respect to the electrode and overlapping with the redistribution wiring as viewed in the first direction; and
a first intermediate layer including a first portion located between the redistribution wiring and the first protective film, wherein
the first portion is in contact with the first protective film,
the first intermediate layer is an insulator and contains an inorganic compound, and
an adhesion strength of the first protective film to the first intermediate layer is higher than an adhesion strength of the first protective film to the redistribution wiring.

2. The semiconductor element according to claim 1, wherein the first portion is in contact with the redistribution wiring.

3. The semiconductor element according to claim 2, wherein the first protective film contains an organic compound.

4. The semiconductor element according to claim 3, wherein a composition of the first intermediate layer includes silicon.

5. The semiconductor element according to claim 3, wherein the redistribution wiring includes a first surface that faces away from the main body in the first direction, and
the first portion covers the first surface.

6. The semiconductor element according to claim 5, wherein the redistribution wiring includes a second surface,
a direction normal to the second surface intersects the first direction, and
the first portion covers the second surface.

7. The semiconductor element according to claim 6, wherein the second surface is inclined relative to the first surface.

8. The semiconductor element according to claim 7, wherein the second surface overlaps with the first surface as viewed in the first direction.

9. The semiconductor element according to claim 8, wherein the first portion includes a first region covering the first surface and a second region covering the second surface, and
a dimension of the second region in a direction orthogonal to the first direction is smaller than a dimension of the first region in the first direction.

10. The semiconductor element according to claim 5, further comprising a second protective film, wherein
the second protective film is located between the main body and the first protective film, and
the second protective film covers a part of the electrode.

11. The semiconductor element according to claim 10, wherein a composition of the second protective film is the same as a composition of the first protective film.

12. The semiconductor element according to claim 11, wherein the first intermediate layer includes a second portion located between the first protective film and the second protective film, and
the second portion is in contact with the first protective film and the second protective film 13. The semiconductor element according to claim 11, wherein the first protective film is in contact with the second protective film.

14. The semiconductor element according to claim 12, wherein the redistribution wiring includes a main portion including the first surface and a contact portion connected to the main portion, and
the contact portion is electrically connected to the electrode and in contact with the second protective film.

15. The semiconductor element according to claim 14, further comprising a terminal electrically connected to the redistribution wiring, wherein
the terminal is located opposite the electrode with respect to the redistribution wiring, and
the terminal is exposed from the first protective film.

16. The semiconductor element according to claim 15, wherein the first protective film includes a first opening penetrating in the first direction and exposing the redistribution wiring,
a part of the terminal is accommodated in the first opening, and
the terminal includes an enlarged portion protruding outward from the first opening as viewed in the first direction.

17. The semiconductor element according to claim 16, further comprising a second intermediate layer that includes a portion located between the first protective film and the enlarged portion, wherein
a composition of the second intermediate layer is the same as a composition of the first intermediate layer, and
the second intermediate layer is in contact with the first protective film and the enlarged portion.

18. The semiconductor element according to claim 16, wherein the enlarged portion is in contact with the first protective film.

19. The semiconductor element according to claim 16, further comprising a third protective film located opposite the second protective film with respect to the main body, and
the third protective film covers the main body.

20. A semiconductor device comprising:
the semiconductor element as set forth in claim 15; and
a base member including a conductive portion, wherein
the semiconductor element is mounted on the base member, and
the terminal is conductively bonded to the conductive portion.
